(19) United States
(12) Patent Application Publication
(10) Pub. No.: US 2020/0373838 A1
(43) Pub. Date: Nov. 26, 2020

(54) INTEGRATED SWITCH MODE POWER SUPPLY DEVICE

(71) Applicant: University of Limerick, Limerick (IE)

(72) Inventors: Patrick Meehan, Pallaskenry, County Limerick (IE); Eamon O Malley, Claremorris, County Mayo (IE); Karl Rinne, Youghal, County Cork (IE)

(21) Appl. No.: 16/766,260

(22) PCT Filed: Nov. 22, 2018
(86) PCT No.: PCT/EP2018/082170

§ 371 Date: May 21, 2020

(30) Foreign Application Priority Data
Nov. 22, 2017 (GB) 1719409.3

(51) Int. Cl. H02M 3/158; H02M 1/14; H02M 1/12; H03H 7/01

(52) U.S. Cl. CPC H02M 3/158; H02M 1/14; H02M 2001/0003; H03H 7/1741; H02M 1/126

(57) ABSTRACT

The invention describes an integrated switch mode power supply device comprising a switch mode regulator having a switching circuit coupled to an input voltage source to generate an output voltage from the input voltage and the switching circuit comprises at least two wide bandgap switches. An Nth order filter circuit is coupled to the switch mode regulator and configured to filter the output voltage to provide a supply voltage to a load, where N is greater than the integer two wherein the filter circuit comprises a LC or RC low pass filter comprising a plurality of LC or RC filter stages having a first filter stage and a last filter stage.

### FIELD

The present disclosure relates to a switch mode power supply device.

### BACKGROUND

Analog, digital and mixed-signal loads all require a similar power supply voltage tolerance adherence. One power supply in common use is a switch mode regulator. Examples of switch mode regulators are a buck regulator, a buck-boost regulator and a boost switch mode regulator.

A switch mode regulator introduces power supply ripple by virtue of its operational characteristic. However, the presence of power supply ripple or noise at an analog or a mixed-signal load causes an undesirable technical effect. This is due to the fact that AC noise on a power supply which is driving an analog circuit may get through into the signal path, and thus be incorrectly interpreted as a signal itself.

U.S. Pat. No. 8,885,376, assigned to Analog Devices Incorporated, describes a switching regulator IC which includes an inductor and a capacitor connected in parallel to form a resonant circuit having an associated notch filter frequency response arranged to attenuate the ripple component of the switching regulator. This requires the tuning of a resonant notch to the ripple's fundamental frequency.

The extent by which ripple can be reduced by such a filtered switch-mode regulator is determined by when the size of the inductor and capacitor of the low pass filter become too large and/or the power-supply transient response becomes too slow. Moreover the local decoupling capacitor on the load will provide some attenuation in the signal which reduces the efficiency of operation. Use of large inductance devices increases the series resistance of the inductor devices, resulting in power loss. An efficient, stable and low physical volume switch mode power supply device is therefore desired.

It is accordingly an object to overcome at least one of the above mentioned problems associated with the use of switch mode regulators.

### SUMMARY

According to the invention there is provided, as set out in the appended claims, an integrated switch mode power supply device or circuit comprising a switch mode regulator having a switching circuit coupled to an input voltage source to generate an output voltage from the input voltage and the switching circuit comprises at least two wide bandgap switches. An Nth order filter circuit is coupled to the switch mode regulator and configured to filter the output voltage to provide a supply voltage to a load, where N is greater than the integer two.

The invention provides a switch mode power supply device which is fabricated on an integrated circuit and suitable for use with both analog and mixed signal loads. The invention makes use of wide bandgap switches, allowing for much higher switching speeds, and positioning of the feedback nodes which results in shrinkage of the physical filter dimensions and allows the entire solution to be fully integrated. By replacing the silicon switches with wide bandgap devices and changing nodes from which the feedback is taken an integrated switch mode power supply device is achieved.

In one embodiment the filter circuit comprises a LC or RC low pass filter comprising a plurality of LC or RC filter stages having a first filter stage and a last filter stage. By including all the filtering needed to adequately remove noise to power a precision analog load, the entire stability of the loop can be compensated for. Otherwise external filters introduce phase changes which are outside the design of the stability of the loop. By using two or more additional filter stages rather than one, the necessary attenuation can be achieved with higher break frequencies. The required inductor values are smaller by a squared law and consequently physical volumes. In other words the invention uses a plurality of stages instead of one will result in the physical volume of the entire filter will be smaller for a given attenuation.

The integrated switch mode power supply device of the present invention provides a number of advantages over the prior art, namely:
Volume, decrease in physical volume is achieved roughly in direct inverse-proportion to the increase in switching frequency.
Efficiency. Use of the consequently-smaller inductor values will decrease the series resistance of the inductors used and save the associated power-loss.
Stability. Because the entire solution is now integrated, the proposed system can now account for all phase and gain changes and design the entire loop to be stable.
EMI screening. The smaller and now integrated, entire solution, lends itself to being placed in a screened outer-shield to prevent both inward and outward harmful EMI.

In one embodiment at least one wide bandgap switch comprise a wide bandgap FET.

In one embodiment the wide bandgap FET comprises a gallium nitride (GaN) device.

In one embodiment at least one wide bandgap switch comprises a gallium nitride (GaN) device.

In one embodiment at least one wide bandgap switch comprises a Silicon Carbide (SiC) device.

In one embodiment a closed feedback loop is configured to feed back an AC signal from a first LC filter stage and a DC signal from a higher ordered LC filter stage.

In one embodiment a closed feedback loop configured to feed back a DC signal from a first LC filter stage and an AC signal from a higher ordered LC filter stage

In one embodiment the closed feedback loop maintains a DC level at the output voltage independent of the load.

In one embodiment the closed loop is stabilised by feeding back a DC or AC signal from after the first filter stage and/or the DC or AC signal from a higher filter stage.

In one embodiment the LC low pass filter comprises a three stage sixth order LC low pass filter.

In one embodiment the switching circuit is configured to operate at switching speeds of 1 MHz or higher.

In one embodiment the integrated circuit comprises a module housing the switch mode regulator and the Nth order filter circuit.

In one embodiment the filter circuit is mounted to a laminate layer dimensioned to support the switch mode regulator.

In one embodiment the load comprises an analog or a mixed signal load.

In another embodiment there is provided integrated switch mode power supply device comprising: a switch mode regulator having a switching circuit coupled to an input voltage source to generate an output voltage from the input voltage and the switching circuit comprises at least one wide bandgap switch; and an Nth order filter circuit coupled to the switch mode regulator and configured to filter the output voltage to provide a supply voltage to a load, where N is greater than the integer two.

In one embodiment there is provided an integrated switch mode power supply device comprising:
a switch mode regulator having a switching circuit coupled to an input voltage source to generate an output voltage from the input voltage and the switching circuit comprises at least two wide bandgap switches; and an Nth order filter circuit coupled to the switch mode regulator and configured to filter the output voltage to provide a supply voltage to a load, where N is greater than the integer two and the filter circuit comprises a LC or RC low pass filter comprising a plurality of LC or RC filter stages having a first filter stage and a last filter stage.

In a further embodiment there is provided a method of operating an integrated switch mode power supply comprising:
is positioning a switch mode regulator, having a switching circuit, to an input voltage source to generate an output voltage from the input voltage and the switching circuit comprises at least two wide bandgap switches; and
coupling a Nth order filter circuit to the switch mode regulator and configuring to filter the output voltage to provide a supply voltage to a load, wherein N is greater than the integer two, wherein the filter circuit comprises a LC or RC low pass filter comprising a plurality of LC or RC filter stages having a first filter stage and a last filter stage.

### BRIEF DESCRIPTION OF THE DRAWINGS

The invention will be more clearly understood from the following description of an embodiment thereof, given by way of example only, with reference to the accompanying drawings, in which:—

FIG. 1 illustrates a Time Domain representation of a switch mode power supply;

FIG. 2 illustrates a Frequency Domain representation of a switch mode power supply;

FIG. 3 shows one embodiment of the switch mode power supply device of the present invention; and

FIG. 4 shows the magnitude of the fundamental switching frequency as measured at the output node of each filter stage of the switch mode power supply device of FIG. 3.

### DETAILED DESCRIPTION OF THE DRAWINGS

The present invention discloses an integrated switch mode power supply comprising a switch mode regulator using wide bandgap switches and a passive filter of higher order than two all of which is integrated in one common IC package.

A switch mode power supply device which is suitable for use with an analog or a mixed signal load is provided. A switch mode regulator having a switching circuit is coupled to an input voltage source is arranged to generate an output voltage from the input voltage and the switching circuit comprises at least two wide bandgap switches. An Nth order filter circuit coupled to the switch mode regulator and configured to filter the output voltage to provide a supply voltage to a load, where N is greater than the integer two.

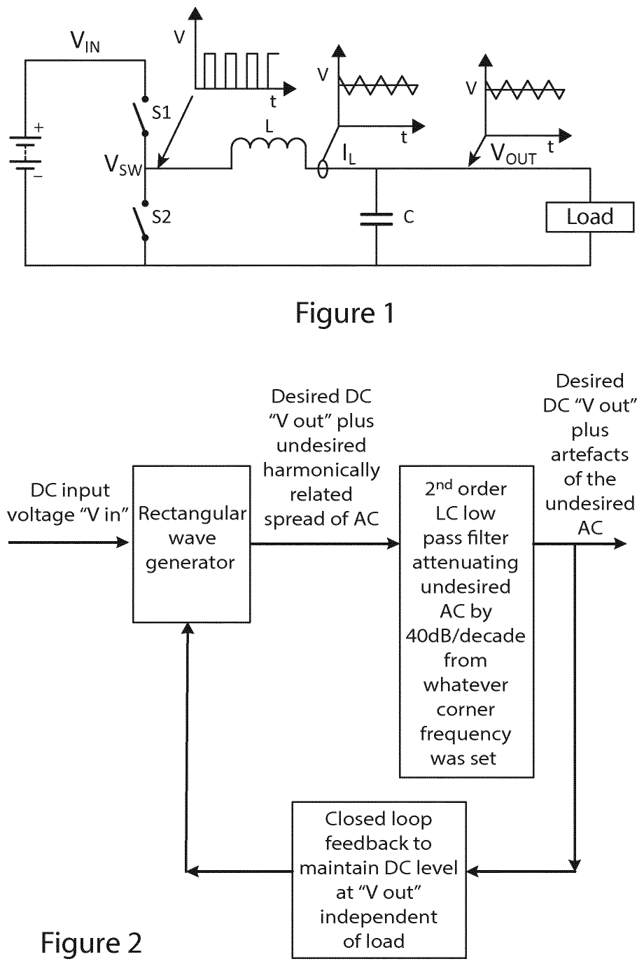

Use of a switch mode supply necessitates the introduction of power-supply ripple by virtue of its operational characteristic. A single, two-pole LC low pass filter is used to reduce the switching ripple as shown in FIG. 1. The limit to that ripple reduction is that the physical inductor and capacitor become too large and the power-supply transient response becomes too sluggish.

The level of residual ripple tolerated by an analog load depends upon that load's AC Power Supply Rejection (AC PSRR) to the frequency in question. Generally, analog loads have little or no rejection to power-supply borne AC noise above 1 MHz.

Wide bandgap FETs, such as GaN devices, allows them to stand off higher voltages than the silicon devices ubiquitous in the industry today, for a given semiconductor area. However, these wide bandgap devices have not been effectively used as high speed, low voltage (<20V) devices. It is considered that silicon is more suitable in that zone. The wide bandgap switch devices also happen to offer lower gate capacitance and the potential for faster switching can be utilised, even though it is not what they are primarily designed for.

According to one aspect the invention is to increase the filter order of the power supply architecture from 2^{nd} order to a higher order, for example 6th or any Nth order in an integrated solution. The silicon FET switches (S1, S2) in FIG. 1 are replaced with wide bandgap devices, such as GaN. The speed of operation can then be selected by a factor selectable by the individual designer. For example an increase in switching speed by an order of magnitude from 600 kHz typical of silicon to 6 MHz. This in turn will allow the inductors and capacitors used to construct the multi-stage low pass filter to be reduced in value and size by the same ratio. The entire filter now takes up 1/10^{th} the area. This in turn now reduces the filter component sizes to below the threshold of acceptability for surface mount integration of the entire regulator and filter.

According to a preferred embodiment the invention is to combine wide bandgap FETs with higher order filters than the second order type used in power supplies today. This will solve the problem of excessive voltage drop associated with linear regulator use and excessive size associated with multi-stage low pass filters. The result will be a fully surface-mount integrated power supply filtered to the extent it is suitable for directly powering sensitive analog or mixed signal loads. The multi-stage filter can be stabilized by feeding back the AC signal from the first filter stage and the DC signal from the last filter stage.

In FIG. 2 a block is shown representing the feedback mechanism used in regulators to increase or decrease the output voltage to maintain a certain relative value to a given reference voltage, in the face of changing load demands, i.e. to “regulate” the output voltage. In the case of a second-order filter, frequencies above the corner frequency of the LC will see a 180 degrees phase shift. This known phase shift is accounted for in the control loop design to prevent an overall 360 degrees situation which is additive and could lead to an unstable situation. But, if an external filter is added to further reduce ripple, it is now outside the control loop and will cause a voltage drop that is dependent on the load current. This further voltage drop is not regulated, and cannot adjust the internal compensation network to account for the additional phase changes at higher frequencies taken on board and stable operation is no longer a guarantee. The invention can be configured to move the point at which the feedback is taken to the output of this final extra filter to pick up that extra voltage drop. By fully integrating the filter as described below, the entire filter stage can be inside the loop and the entire phase shift can be compensated for by the regulator design. The feedback may now be separated out into AC and DC, where AC allows compensation for phase shifts with frequency and DC allows for the combined voltage drops. AC may be taken after the first, second or later stages. DC is preferably taken from a later stage.

### EXAMPLE EMBODIMENT

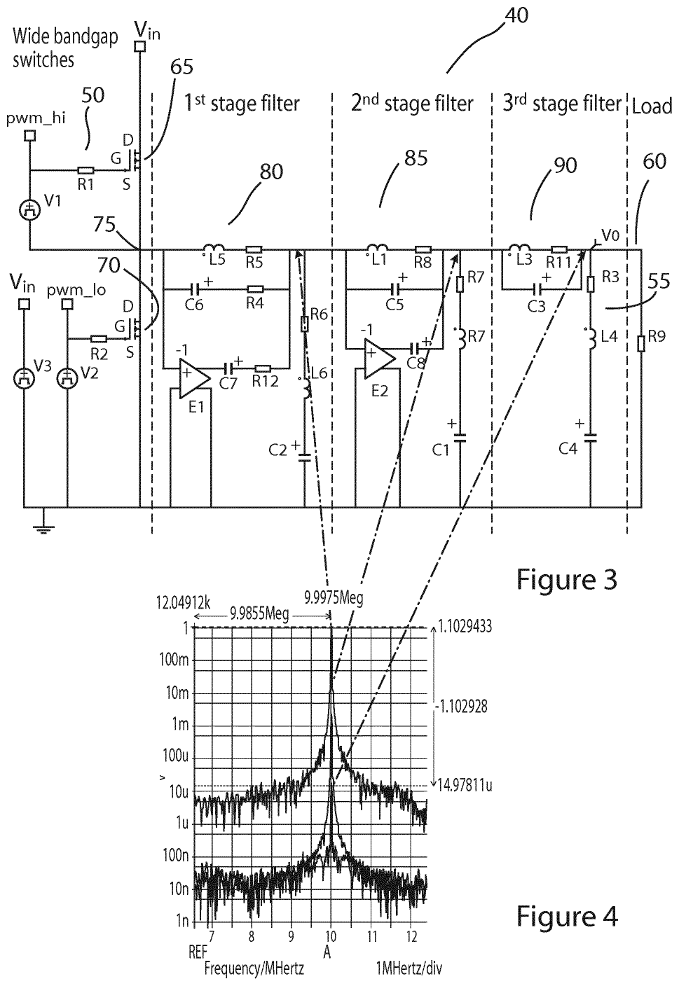

FIG. 3 shows one embodiment of the integrated switch mode power supply device of the present invention. In the embodiment shown, the integrated device 40 comprises a switch mode regulator comprising an input voltage source 45 and a switching circuit 50 comprising a first switch 65 and a second switch 70, and the low pass filter comprises a third stage sixth order LC low pass filter 55.

Each of the first switch 65 and the second switch 70 comprise a wide bandgap FET. In the embodiment of the invention shown in FIG. 3, each wide bandgap FET comprises a gallium nitride (GaN) device. Such a wide bandgap FET is manufactured by EPC and GAN Systems. However, it will be appreciated that any other suitable wide bandgap device could equally well be used instead, such as for example Silicon Carbide (SiC).

The first switch 65 and the second switch 70 are connected in series such that the source of switch 65 and the drain of switch 70 share a common node 75. The drain of switch 65 is connected to the input voltage source 45 while the source of switch 70 is connected to ground.

The three stage sixth order low pass filter 55 comprises a LC low pass filter having a first LC stage 80, a second LC stage 85 and a third LC stage 90, such that each LC each stage comprises a second order low pass LC filter. The input of the first stage 80 is coupled to the common node 75 of the switching circuit 50 of the switch mode regulator, while the output of the first stage 80 is coupled to the input of the second stage 85. The output of the second stage 85 is coupled to the input of the third stage 90. The output of the third stage 90 is then coupled to a load 60 in order to provide the desired output voltage to the load 60. A closed feedback loop maintains the DC level at this output voltage independent of the load.

In order to ensure that the switch mode power supply device remains stable, the closed loop is stabilised by feeding back the AC signal from the first filter stage and the DC signal from the final filter stage.

The wide energy band of the switches 65 and 70 allows the switches to stand off higher voltages for a given semiconductor area and have a lower gate capacitance than the silicon switches used in conventional power supply devices. Furthermore, due to the fact that the switches 65 and 70 are wide bandgap FETs, the switching circuit 50 can be configured to achieve very high switching speeds, for example 1 MHz or higher. This represents a significant increase over the switching speeds of around 600 kHz achievable by the silicon switching elements used in the conventional switch-mode regulators previously described. The value of the switching speed for a particular device can be determined by the designer of the device. This increased switching speed allows the inductors and capacitors used to construct the low pass filter 55 to be reduced in value and size by the same ratio. As a result, the dimensions of the components of the filter 55 of the power supply device are below the threshold of acceptability for surface mount integration.

It should be appreciated that while in the described embodiment of the invention the switching circuit comprises two switching elements, in an alternative embodiment of the invention, the switching circuit may comprise a single switch. This can be achieved by replacing the bottom switch with a diode. Aa anode is connected to ground. When the top switch is turned off, the back-emf from the inductor will turn on the diode.

As noted above, the components of the switch mode power supply device of the present invention are housed as an integrated circuit. The housing can be any form of integrated, self-contained package. For example, in one embodiment, the integrated circuit is configured such that the filter circuitry is mounted to a laminate which also supports the switch mode regulator die. The laminate is then encapsulated within, for example, a mold cap. Wire bonds connect the circuitry to the package's leads. Alternatively, the integrated circuit may comprise a module-type package, where the switch mode regulator die and the filter circuitry are housed within a module.

In another alternate embodiment of the device, the filter circuitry is mounted to the lead frame of the integrated circuit package, which may be specifically designed or modified to accommodate the circuitry.

The operation of the switch mode power supply device of FIG. 3 is illustrated in FIG. 2. Thus, during operation, switch 65 and switch 70 of the switch mode regulator are configured to alternatively switch between an open and a closed state at a predetermined switching speed. This transforms the DC voltage output from the source 45 into a voltage waveform at the common node 75, which may be rectangular or square. The voltage waveform comprises the desired DC supply voltage as well as an undesired harmonically related spread of AC voltage. This output voltage from the switch mode regulator is then input into the three stage sixth order low pass filter 55. Each consecutive stage of the low pass filter 55 attenuates the undesired AC voltage such that the voltage at the output of the third stage 90 of the filter 55 which corresponds to the supply voltage provided to the load 60 does not contain AC noise above a predetermined threshold value. The closed feedback loop then maintains the DC level of the output voltage independent of the load.

FIG. 4 shows the magnitude of the fundamental switching frequency as measured at the output node of each of the three filter stages of the switch mode power supply device shown in FIG. 3. It can be seen that the final magnitude of the fundamental frequency (blue trace) is 15 uV, in this specific arrangement.

The switch mode power supply device of the present invention provides a number of advantages over conventional switch mode power supplies. Firstly, due to the fact that the switching speed achievable by the device is much larger than that achievable by conventional power supplies, it enables the dimensions of the filter circuitry to be reduced to a size which is compatible with fabricating the power supply circuit as a surface-mount integrated circuit which is suitable for directly powering sensitive analog or mixed signal loads.

Furthermore, due to the fact that the power supply circuit of the present invention is integrated, the designer of the power supply circuit can now account for all phase and gain changes, and thus design the entire loop to be stable.

In addition, as a result of the power supply circuit of the present invention being smaller and integrated, the circuit is suitable for placement in a screened outer-shield, in order to prevent both inward and outward harmful electromagnetic interference (EMI).

The present invention also provides a more efficient power supply device than conventional devices. This is due to the fact that inductors of smaller inductance values can be used in this device, which leads to a corresponding decrease in the series resistance of such inductors. As a result, the power loss associated with the device of the present invention is less than the power loss associated with conventional power supply devices.

In the context of the present invention the terms “Integrated” to mean housed within a common IC package with the switching-regulator circuitry, as hereinbefore described with reference to the description and/or figures.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. An integrated switch mode power supply device comprising:
a switch mode regulator having a switching circuit coupled to an input voltage source to generate an output voltage from the input voltage and the switching circuit comprises at least two wide bandgap switches; and
an Nth order filter circuit coupled to the switch mode regulator and configured to filter the output voltage to provide a supply voltage to a load,
where N is greater than the integer two and the filter circuit comprises a LC or RC low pass filter comprising a plurality of LC or RC filter stages having a first filter stage and a last filter stage.

2. The integrated switch mode power supply device of claim 1, wherein at least one wide bandgap switch comprises a wide bandgap FET.

3. The integrated switch mode power supply device of claim 2 wherein the wide bandgap FET comprises a gallium nitride (GaN) device.

4. The integrated switch mode power supply device of claim 1, wherein at least one wide bandgap switch comprises a gallium nitride (GaN) device.

5. The integrated switch mode power supply device of claim 1, wherein at least one wide bandgap switch comprises a Silicon Carbide (SiC) device.

6. The integrated switch mode power supply device of claim 1, further comprising:
a closed feedback loop configured to feed back an AC signal from a first LC filter stage and a DC signal from a higher ordered LC filter stage.

7. The integrated switch mode power supply device of claim 1, further comprising:
a closed feedback loop configured to feed back a DC signal from a first LC filter stage and an AC signal from a higher ordered LC filter stage.

8. The integrated switch mode power supply device of claim 1, wherein the LC low pass filter comprises a three stage sixth order LC low pass filter.

9. The integrated switch mode power supply device of claim 1, wherein a closed feedback loop maintains a DC level at the output voltage independent of the load.

10. The integrated switch mode power supply device of claim 1, wherein a closed feedback loop is stabilized by feeding back a DC or AC signal from after the first filter stage and/or the DC or AC signal from a higher filter stage.

11. The integrated switch mode power supply device of claim 1, wherein the switching circuit is configured to operate at switching speeds of 1 MHz or higher.

12. The integrated switch mode power supply device of claim 1, wherein an integrated circuit comprises a module housing the switch mode regulator and the Nth order filter circuit.

13. The integrated switch mode power supply device of claim 1, wherein the filter circuit is mounted to a laminate layer dimensioned to support the switch mode regulator.

14. The integrated switch mode power supply device of claim 1, wherein the load comprises an analog or a mixed signal load.
